(19) United States
(12) Patent Application Publication
(10) Pub. No.: US 2021/0247002 A1
(43) Pub. Date: Aug. 12, 2021

(54) SPINE BAR CLIP BRACKET, SYSTEM, AND METHOD OF MANAGING CABLES

(71) Applicant: CXtec Inc., Syracuse, NY (US)

(72) Inventor: Richard M. Dallmann, Clay, NY (US)

(21) Appl. No.: 16/788,474

(22) Filed: Feb. 12, 2020

(51) Int. Cl. F16L 3/22; H05K 7/14; H05K 5/02; F16L 3/06; F16L 3/227; F16L 3/24

(52) U.S. Cl. CPC F16L 3/221; H05K 7/1491; F16L 3/24; F16L 3/06; F16L 3/227; H05K 5/0247

(57) ABSTRACT

A bracket for managing cables and a system for managing cables using a plurality of brackets are disclosed. The bracket includes a u-shaped body having an open end, closed end, and two side legs. The bracket also includes a pair of first projections extending from surfaces of the side legs towards an interior of the bracket located between the two side legs. In addition, the bracket includes a pair of second projections extending from the two side legs towards the interior of the bracket, each of the second projections spaced away from the closed end of the bracket and extending from a different side leg. Furthermore, the bracket includes a plurality of external projections disposed on an outer surface of each of the two side legs and a plurality of large clips disposed on the outer surface of the two side legs.

### BACKGROUND

Cable management is a necessity in computer network servers and data centers. Without proper management, cables can become slack and intertwined, resulting in waste, heat build-up, snags, and connection identification problems. This can lead to network down time, causing loss of business and revenue for the company affected. Therefore, an improved device for managing cables is needed in computer network servers and data centers.

### SUMMARY

At least one aspect of the disclosure is directed to a bracket for managing cables. The bracket includes a u-shaped body having an open end, closed end, and two side legs. The bracket also includes a pair of first projections extending from surfaces of the side legs towards an interior of the bracket located between the two side legs, with each of the first projections extending from a different side leg. The bracket further includes a pair of second projections extending from the two side legs towards the interior of the bracket, each of the second projections spaced away from the closed end of the bracket and extending from a different side leg, and the pair of first projections is located closer to the open end of the bracket than the pair of second projections. The bracket also includes a plurality of small clips disposed on an outer surface of each of the two side legs, each of the plurality of small clips configured for holding a first portion of a cable furcation point, and a plurality of large clips disposed on the outer surface of the two side legs, each of the large clips configured for holding a second portion of the cable furcation point.

In some embodiments, the plurality of small clips are disposed at a first vertical position of the u-shaped body, a first portion of the plurality of large clips is disposed at a second vertical position of the u-shaped body, and another portion of the plurality of large clips is disposed at a third vertical position of the u-shaped body, wherein vertical refers to a direction normal to the lengths the side legs. In some embodiments, the plurality of large clips alternate along the lengths of the side legs between being positioned at the second vertical position and the third vertical position. In some embodiments, each of the plurality of small clips is vertically aligned to a respective large clip.

In some embodiments, the closed end of the u-shaped body comprises a curved surface concave to an interior of the bracket. In some embodiments, the closed end of the u-shaped body is configured for routing cables along a length of a spine bar of a computer cabinet. In some embodiments, the bracket can affix to the spine bar using a single first projection. In some embodiments, the first side leg is spaced from the second side leg by about the width of a main frame computer spine bar. In some embodiments, the first projections are longer vertically than the second projections.

In some embodiments, the bracket further includes a pair of third projections, each of the third projections positioned on a surface of one of the two side legs, vertically aligned with one of the second projections. In some embodiments, each of the plurality of small clips includes a pair of straight opposing prongs that are sufficiently flexible or rigid, shaped and sized to securely hold the first portion of the cable furcation point. In some embodiments, each of the plurality of large clips includes a pair of curved opposing prongs that are sufficiently flexible or rigid, shaped and sized to securely hold the second portion of the cable furcation point.

At least one aspect of the disclosure is directed to a system for managing cables. The system includes a plurality of brackets as described herein and a computer cabinet for storing a plurality of computing devices having network ports therein. In some implementations, the computer cabinet includes a spine bar. In some embodiments, the plurality of brackets are reversibly attached to the spine bar. In some embodiments, each of the plurality of brackets is configured to fasten a plurality of cables along a length of the spine bar.

In some embodiments, the spine bar includes a plurality of slots wherein each of the plurality of slots is configured for snapping in a pair of first projections from a bracket of the plurality of brackets. In some embodiments, the plurality of brackets are attached to the spine bar along the length of the spine bar at different vertical heights from a bottom of the cabinet.

In some embodiments, at least one of the plurality of brackets includes a plurality of cable furcation points clipped into an exterior surface of the bracket and a plurality of cables routed through an interior space of the bracket located between the spine bar and the computing devices in the cabinet, where each of the cables in the interior space includes a furcation point clipped into at least one of the other brackets. In some embodiments, the pair of first projections in each of the plurality of brackets is configured to restrict rotation of the bracket. In some embodiments, the closed end of each of the plurality of brackets comprises a curved surface concave to an interior of the bracket, the curved surface configured for routing cables along the length of the spine bar within the concave portion of the curved surface.

At least one aspect of the disclosure is directed to a method of assembling a system for managing cables. The method includes providing a plurality of brackets as described herein and providing a computer cabinet for storing a plurality of computing devices having network ports therein. In some implementations, the computer cabinet includes a spine bar having a plurality of slots along the length of the spine bar at different vertical heights from a bottom of the cabinet. The method also includes routing a plurality of cables within an interior space of a first bracket, attaching the first bracket to a first slot of the spine bar, and placing a first portion of a first cable furcation point in a small clip of the first bracket and placing a second portion of the first cable furcation point in a large clip of the first bracket. In some embodiments, the small clip is vertically aligned to the large clip. The method also includes connecting an end of the first cable to a first computing device in the computer cabinet.

In some implementations, the method further includes routing the plurality of cables within an interior space of a second bracket, attaching the second bracket to a second slot of the spine bar, the second slot positioned at a different vertical position from the first slot, placing a first portion of a second cable furcation point in a small clip of the second bracket and placing a second portion of the second cable furcation point in a large clip of the second bracket, the small clip is vertically aligned to the large clip, and connecting an end of the second cable to a second computing device in the computer cabinet.

At least another aspect of the disclosure is directed to a method of assembling a system for managing cables. The method includes providing a plurality of brackets and providing a computer cabinet for storing a plurality of computing devices having network ports therein. In some implementations, the computer cabinet includes a spine bar having a plurality of attachment locations along the length of the spine bar at different vertical heights from a bottom of the cabinet. The method also includes routing a plurality of cables within an interior space of a first bracket, attaching the first bracket to a first attachment location of the spine bar, placing a furcation point of a first cable in the first bracket, and connecting an end of the first cable to a first computing device in the computer cabinet. In addition, the method includes routing the plurality of cables within an interior space of a second bracket, attaching the second bracket to a second attachment location of the spine bar, the second attachment location positioned at a different vertical position from the first attachment location, placing a furcation point of a second cable in the second bracket, and connecting an end of the second cable to a second computing device in the computer cabinet.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1A shows a layout view of a bracket for managing cables, according to an illustrative implementation;

FIG. 1B shows a perspective view of the bracket, according to an illustrative implementation;

FIG. 1C shows a cross-sectional view of the bracket, according to an illustrative implementation;

FIG. 1D shows a perspective view of the bracket attached to a spine bar, according to an illustrative implementation;

FIG. 1E shows a top-down view of the bracket attached to the spine bar, according to an illustrative implementation;

FIG. 2A illustrates a system for managing cables using a bracket, according to illustrative implementations;

FIG. 2B illustrates a system for managing cables using a plurality of brackets, according to illustrative implementations;

FIG. 3 is a flowchart for an example method of assembling a system for managing cables, according to an illustrative implementation.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 180 degrees or at other orientations) and the spatially relative descriptors used herein may likewise be interpreted accordingly. In addition, the term “made of” may mean either “comprising” or “consisting of.”

The disclosure as described herein relates to a bracket and a system including a plurality of brackets mounted to a spine bar of computer cabinet or a computer storage structure that houses a plurality of computing devices, such as computers, mainframe computers, or one or more servers or server racks in a network environment. In such environments, the computing devices are connected via cables, such as, Ethernet cables or fiber optics cables, to form the computing network within the network or externally to other networks. The computing devices in a given computer cabinet are typically connected to a central networking device such as a hub or top-of-rack switch, which may be located on the top, at the bottom, or elsewhere in or on the computer cabinet. This central networking device serves as a point of contact to a remainder of the computer network and to route communications between computing devices housed in the computer cabinet. To properly manage the cables within a network or even within a computer cabinet that contains a plurality of computing devices, the cables coupled to the computing devices can be routed to the central computing device along a spine bar of the cabinet.

To ease the cabling burden, cables are often provided in cable harnesses that include a trunk portion and a plurality of legs. The trunk portion includes all of the cables that make up the harness within a single jacket, whereas the legs contain one or in some cases two cables within separate jackets. For example, a cable harness may include 16 optical fibers under a common jacket in the trunk portion, split up into 8 fiber pairs in 8 separate legs. In some implementations the trunk of the cable harness may include 32 optical fibers, which split into 16 fiber pairs in 16 separate legs. Other numbers of fibers or other types of cables or wires can be included in the cable harness without departing from the scope of the disclosure.

The point at which the trunk splits into its legs is referred to as a furcation point. The furcation point includes a neck portion that receives the trunk of the cable harness. The furcation point then broadens at a shoulder portion, where the trunk is split into its separate legs, into a body portion, which includes a jacket that surrounds all of the jacketed legs for a short distance. The diameter of the body portion of the furcation point can range between 1.5-3.0 times the diameter of the neck of the furcation point. Outside of the body jacket of the furcation point, each of the legs of the cable harness can be individually routed to its respective network port or ports. In some implementations, the neck of the furcation point can range from about 0.25 cm to 1.0 cm in length and the body of the furcation point can range from about 1.0 cm to about 5 cm in length.

To provide for organized and stable cabling routing, it can be beneficial for the furcation point of a cable harness to be releasably fixed in position. This releasably fixed position prevents changes in orientation of the furcation point that could damage the cables at the furcation point. It also keeps maintains the division of the cabling harness at a desired location, e.g., relatively close to the network ports each of the legs will couple too, facilitating easy identification of correspondence between cable legs, cable trunks, and computer devices.

Accordingly, the disclosure as described herein relates to a bracket for managing cables, a system for managing cables, and a method for assembling a system for managing cables. In some implementations, the cables refer to fiber optics cables, Ethernet cables, or any suitable cables for use in networking environments. The brackets provide fixtures for releasable fixation of cable harness furcation points, as well as for paths for routing trunk portions of cable harnesses along a computer cabinet in a neat and organized fashion.

Various implementations of the bracket, system, and method disclosed herein employ a u-shaped body having an open end, a closed end, and two side legs. In some embodiments, the disclosed bracket includes a pair of first projections extending from surfaces of the side legs towards an interior of the bracket located between the two side legs. The brackets also can include a pair of second projections extending from the two side legs towards the interior of the bracket. Each of the second projections is spaced away from the closed end of the bracket and extends from a different side leg, and the pair of first projections is located closer to the open end of the bracket than the pair of second projections. The first projections can be used to secure the bracket into slots formed in various positions along the length of a computer cabinet spine bar. The second projections are positioned to abut the computer device-facing side of the spine bar, to help avoid rotation or the bracket and to facilitate proper place of the bracket on the spine bar. The space between the second projections and the closed end of the bracket can be used to route trunk portions of cable harnesses that have furcation points at other locations in the computer cabinet.

In some embodiments, the bracket also includes a plurality of large clips for releasably receiving body portions of respective cable harness furcation points. The bracket also includes small clips disposed on an outer surface of each of the two side legs to receive the necks of the furcation points. The small clips help prevent the furcation points being pulled out of the brackets along the length of the spine bar while the cables are being routed. In some embodiments, each of the plurality of small clips of the bracket includes a pair of straight opposing prongs that are sufficiently flexible or rigid, shaped and sized to hold the first portion of the cable furcation point and prevent movement of a furcation point along at least one vertical direction. In some embodiments, each of the plurality of large clips of the bracket includes a pair of curved opposing prongs that are sufficiently flexible or rigid, shaped and sized to securely hold the second portion of the cable furcation point.

In some embodiments, the plurality of small clips of the disclosed bracket are disposed at a first vertical position of the u-shaped body of the bracket. The “vertical position” as used herein refers to a direction normal to the lengths of the side legs of the brackets. A first portion of the plurality of large clips can be disposed at a second vertical position of the u-shaped body, and another portion of the plurality of large clips is disposed at a third vertical position of the u-shaped body. In some embodiments, the vertical positions of the plurality of large clips alternate along the lengths of the side legs between being positioned at the second vertical position and the third vertical position. In some embodiments, each of the plurality of small clips is vertically aligned to a respective large clip. The alternation allows for tighter spacing of the large clips, as the prongs that make up the clips are given room to deform outwards to accept a furcation point body without interfering with the prongs of adjacent clips.

In some embodiments, the closed end of the u-shaped body of the bracket includes a curved surface concave to an interior of the bracket. In some implementations the concave surface of the closed end of the u-shaped body is joined to the legs of the u-shaped body on either side by surfaces having a convex curvature relative to the interior space of the bracket. In some embodiments, the closed end of the u-shaped body is configured for routing cables or trunk portions of cable harnesses along a length of a spine bar of a computer cabinet. In some embodiments, the first side leg is spaced from the second side leg by about the width of a main frame computer spine bar. In some embodiments, the first projections are longer vertically than the second projections. In some embodiments, the disclosed bracket further includes a pair of third projections, each of the third projections of the bracket is positioned on a surface of one of the two side legs, vertically aligned with one of the second projections.

According to the various implementations as disclosed herein, a system for managing cables includes a plurality of brackets as described herein and a computer cabinet that includes a main or a mini spine bar. The computer cabinet stores a plurality of computing devices having network ports therein. In some embodiments, the plurality of brackets are reversibly or releasably attached to the spine bar. In some embodiments, each of the plurality of brackets is configured to secure a plurality of cable harnesses along a length of the spine bar. Furcation points of such cable harnesses releasably couple to clips included on an outer surface of the brackets and trunk portions of other cable harnesses can be routed through a space left between the spine bar and the closed end of the respective brackets.

According to the various implementations as disclosed herein, a method of assembling a system for managing cables includes using a plurality of brackets as described herein. In some implementations, the method includes using the brackets in a computer cabinet, which stores a plurality of computing devices having network ports therein. In some implementations, the computer cabinet includes a spine bar having a plurality of slots along the length of the spine bar at different vertical heights from a bottom of the cabinet. In some implementations, the method includes routing a plurality of cables (for example the trunk portions of a plurality of cable harnesses) within an interior space of a first bracket, attaching the first bracket to a first slot of the spine bar, placing a first portion of a first cable furcation point of another cable harness in a small clip of the first bracket and placing a second portion of the first cable furcation point in a large clip of the first bracket. In some embodiments, the small clip is vertically aligned to the large clip. The disclosed brackets in various implementations are capable of securing 8 MPO-LC Direct Attached harnesses, and depending on base-8 or base-12 harness construction, a capacity of 32 to 48 ports per clip can be implemented on the disclosed bracket.

As disclosed herein, an advantage of the disclosed bracket, system, and method includes a better cable management tool, system and method that reduces cable slacking, wasteful intertwining, snagging, and troublesome connection identification problems, not to mention heat build-up. The disclosed bracket, system and method can lead to reduced network down time. As disclosed herein, the disclosed bracket, system, and method can greatly improve cable management in computer network servers and data centers. For example, the disclosed bracket can be used in a high-density fiber rack, server cabinet, or mainframe cabinet where space is severely limited. The disclosed bracket, system and method can provide a tool, a system and a method to organize cable links without interfering at various connection points. The bracket, system, and method can be applied for easy and efficient routing of the cables while providing supports for various furcation points in the cables, which in turn offers horizontal stability at furcation points.

The following figures and descriptions with respect to the figures provide additional details of the various embodiments of a bracket for managing cables, various implementations of a system comprising a plurality of brackets for managing cables, and various implementations of a method of assembling a system for managing cables.

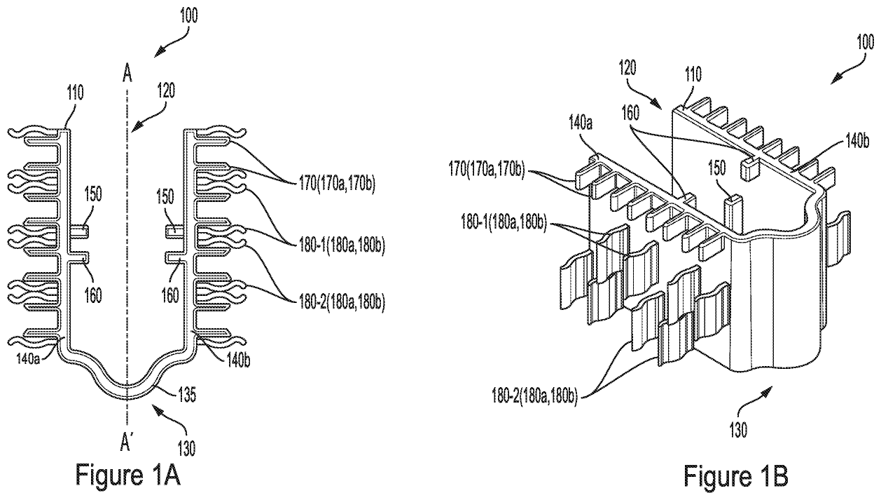

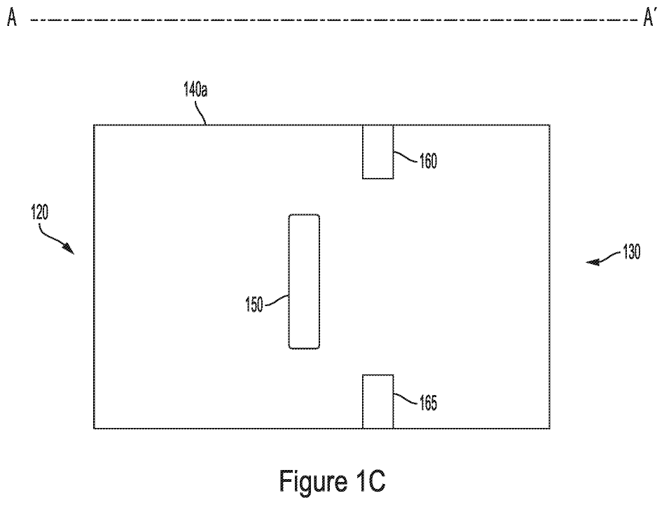

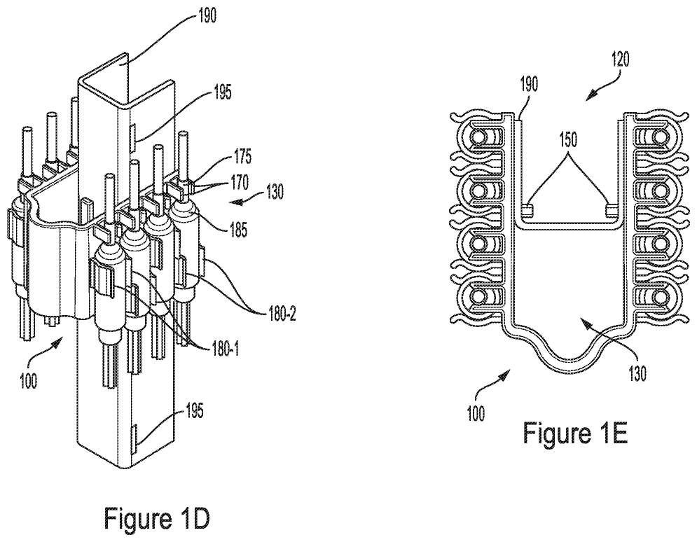

FIG. 1A shows a layout view of a bracket 100 for managing cables and FIG. 1B shows a perspective view of the bracket 100, according to an illustrative implementation. FIG. 1C shows a cross-sectional view A-A′ of the bracket, according to an illustrative implementation. FIG. 1D shows a perspective view of the bracket attached to a spine bar and FIG. 1E shows a top-down view of the bracket attached to the spine bar, according to an illustrative implementation. As shown in FIGS. 1A, 1B, 1C, 1D, and 1E, the bracket 100 includes a u-shaped body 110 having an open end 120, a closed end 130, and two side legs 140a and 140b (collectively referred to as “side legs 140”). The bracket 100 also includes a pair of first projections 150 extending from surfaces of the side legs 140 towards an interior of the bracket 100 located between the two side legs 140, with each of the first projections 150 extending from a different side leg 140a and/or 140b. The bracket 100 also includes a pair of second projections 160 extending from the two side legs 140 towards the interior of the bracket 100, each of the second projections 160 spaced away from the closed end 130 of the bracket 100 and extending from a different side leg 140a and/or 140b, and the pair of first projections 150 is located closer to the open end 120 of the bracket 100 than the pair of second projections 160. As shown in the cross-sectional view A-A′ of FIG. 1C, the bracket 100 also includes a third projection 165 disposed on the interior of the side leg 140b. The third projection 165 is vertically aligned with the second projection 160 as shown in FIG. 1C. An opposing third projection 165 is located on the other side leg 140a, not seen in the cross-sectional view of FIG. 1C.

The bracket 100 also includes a plurality of small clips 170 disposed on an outer surface of each of the two side legs 140. The bracket 100 also includes a plurality of large clips 180 disposed on the outer surface of the two side legs 140. The plurality of large clips 180 includes a first portion 180-1 and a second portion 180-2, which are collectively referred to herein as the plurality of large clips 180.

In some implementations of the bracket 100, the plurality of small clips 170 are disposed at a first vertical position of the u-shaped body 110. In some implementations, the first portion 180-1 of the plurality of large clips 180 are disposed at a second vertical position of the u-shaped body 110, and the second portion 180-2 of the plurality of large clips 180 are disposed at a third vertical position of the u-shaped body 110. In this instance, vertical refers to a direction normal to the lengths the side legs 140.

In some implementations of the bracket 100, the plurality of large clips 180 alternate along the lengths of the side legs 140 between being positioned at the second vertical position and the third vertical position. For example, if a large clip 180 belongs to the first portion 180-1 which is positioned at a second vertical position, then the adjacent large clip 180 that belongs to the second portion 180-2 is positioned at a third vertical position. In some implementations, the alternation of the first portion 180-1 and 180-2 between the two different vertical positions allows placing a higher number of large clips 180 compared to if the large clips 180 were placed in the same vertical position. If the large clips 180 were positioned in the same vertical position, the large clips 180 would have to be spaced farther apart to accommodate expansion of the curved opposing prongs 180a and 180b during the insertion and removal of the body of a furcation point 185. In some implementations, the offset vertical positions allows the curved opposing prongs 180a and 180b of each of the large clips 180 to expand and contract as the body portion of the furcation point 185 is being placed in and out of the large clips 180, and thus allows for placing the large clips 180 closer to each other. By placing a row of the first portion 180-1 of large clips 180 closer to the bottom of the bracket 100 and a row of the second portion 180-2 of large clips 180 towards the middle of the bracket 100, the prongs 180a and 180b of adjacent large clips 180 do not interfere with each other.

In some implementations of the bracket 100, each of the plurality of small clips 170 is vertically aligned to a respective large clip 180, as shown in FIGS. 1A and 1D. In some implementations, each of the plurality of small clips 170 is configured for holding a first portion (e.g., the neck) of a cable furcation point 175 and each of the large clips 180 is configured for holding a second portion (e.g., the body) of the cable furcation point 185.

According the various implementations disclosed herein, the closed end 130 of the u-shaped body 110 is configured for routing cables (e.g. the trunk portions of cable harnesses) along a length of a spine bar 190 of a computer cabinet. For example, for a computer cabinet with three four vertical rows or shelves of computing devices and a central networking device at the top of the computer cabinet, the trunk portions of the cable harnesses that would couple to the computing devices in the second, third, and fourth rows of computing devices from the top can be routed through the interior portion of the top bracket located near the closed end of the bracket 100, between the spine bar of the cabinet and the computing devices. The second bracket from the top can having trunk portions of cable harnesses connecting to the bottom two racks similarly routed through its in interior space. Furcation points of cable harnesses intended to be connected to the computing devices in the second row are coupled into the clips of the second bracket. Similar routing and furcation point securing can be used for the third and fourth brackets associated with the third and four rows.

Accordingly, in some implementations, the cables are routed within an interior space of the bracket 100 near the closed end 130. In some implementations, the interior space of the bracket 100 near the closed end 130 functions as a cable routing loop and funnel for proper harness routing and positioning. In some implementations of the bracket 100, the closed end 130 of the u-shaped body 110 includes a curved surface 135 concave to the interior of the bracket 100. In some embodiments, the curved surface 135 includes several portions which may have different curvatures (e.g., concave or convex with respect to the interior of the bracket 100) along the closed end 130. In some embodiments, the curved surface 135 of the closed end 130 is configured to provide sufficient rigidity, flexibility, and compliance so that the bracket 100, via the first projections 150 of the two side legs 140, can securely latch onto the spine bar 190. In some implementations, the bracket 100 can affix to the spine bar 190 using a single first projection 150. In some implementations of the bracket 100, the first side leg 140a is spaced from the second side leg 140b by about the width of the spine bar 190, for example, of a main frame computer. In some implementations, the first projections 150 are longer vertically than the second projections 160.

In some embodiments, the spine bar 190 includes one or more slots 195. In some implementations, each of the slots 195 is configured for receiving one of the first projections 150 of a bracket 100. In some implementations, the spine bar 190 includes a plurality of slots 195 to accommodate a plurality of brackets 100. In some embodiments, the plurality of brackets 100 are attached to the spine bar 180 along the length of the spine bar 195 at different vertical heights from a bottom of the cabinet.

In some implementations of the bracket 100, each of the plurality of small clips 170 includes a pair of straight opposing prongs 170a and 170b that are sufficiently flexible or rigid, shaped and sized to hold the neck of the cable furcation point 175. During the connection, the prongs 170a and 170b help maintain the orientation of the furcation point while limiting longitudinal or rotational movement of the first and second portions of the furcation point. In such implementations, the pair of straight opposing prongs 170a and 170b can be referred to as alignment guides, and thus, each of the plurality of small clips 170 can be described as an alignment guide having two alignment prongs 170a and 170b. In some implementations, each of the plurality of small clips 170 includes a pair of straight opposing prongs 170a and 170b that have a separation distance between the two prongs that is large enough to accommodate the first portion of the cable furcation point 175, but is small enough to prevent the second portion of the cable furcation point 185 from sliding through the prongs 170a and 170b. In such implementations, each of the plurality of small clips 170 helps constrain the movement of the furcation point relative to the positions of the small clip 170 and the large clip 180. In such implementations, each pair of the small clips 170 and large clips 180 also helps constrain the movement of the furcation point vertically along the spine bar 190.

In some embodiments, the bracket 100 has a length of about 50 mm to about 80 mm along the lengths of the side legs 140 from the open end 120 to the closed end 130. In some embodiments, the bracket 100 has a vertical height (in the direction normal to the lengths of side legs 140) of about 30 mm to about 50 mm along the vertical positioning of the small clips 170, a first portion of the large clips 180-1 and the second portion of the large clips 180-2. In some embodiments of the bracket 100, the distance between the first projections 150 and the second projections 160, as shown in the layout view of FIG. 1A, ranges from about 15 mm to about 20 mm, and with a preferred embodiment of 17 mm. Similarly, the distance between the third projections 165 and the first projections 150 ranges from about 15 mm to about 20 mm, and with a preferred embodiment of 17 mm. In some embodiments, the distance between two adjacent clips 180-1 ranges from about 6 mm to about 12 mm, and with a preferred embodiment of 9 mm. Similarly, the distance between two adjacent clips 180-2 ranges from about 6 mm to about 12 mm, and with a preferred embodiment of 9 mm. In some embodiments, the distance between the first leg 140a and the second leg 140b ranges from about 20 mm to about 35 mm, and with a preferred embodiment of 26 mm.

In some implementations, the bracket 100 is made from a plastic, a polymer, a metal or a composite.

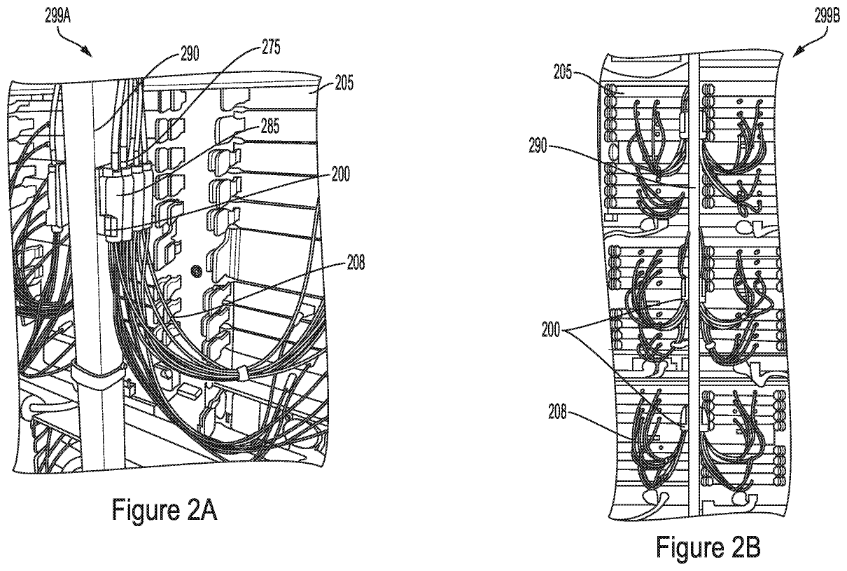

FIG. 2A illustrates a system 299A for managing cables using a bracket 200 and FIG. 2B illustrates a system 299B for managing cables using a plurality of brackets 200, according to illustrative implementations. As illustrated in FIG. 2A, the system 299A includes a bracket 200 that is attached to a spine bar 290 of a computer cabinet 205 (also referred to herein as a computer storage structure that houses a plurality of computing devices). Similarly, the system 299B illustrated in FIG. 2B includes a plurality of brackets 200 attached to the spine bar 290 of the computer cabinet 205. The bracket 200 and the plurality of brackets 200 are similar or substantially the same as the bracket 100 as illustrated and described with respect to FIGS. 1A, 1B, 1C, and 1D, therefore, the details of the bracket 200 and the plurality of brackets 200 will not be further described herein.

As shown in FIGS. 2A and 2B, the computer cabinet 205 includes a plurality of computing devices each having network ports to which a plurality of cables 208 are connected. According to various implementations, the system 299A includes the bracket 200 configured to affix a plurality of cables 208 at a position of the spine bar 290. The cables are affixed at the furcation point of the cable harness including the cables. In some implementations, the system 299B includes the plurality of brackets 200 each of which is configured to fasten the plurality of cables 208 at respective furcation points along a length of the spine bar 290. In some embodiments, the spine bar 290 includes the plurality of brackets 200 that are attached (e.g., reversibly, temporarily or permanently) to the spine bar along the length of the spine bar 290 at different vertical heights from a bottom of the computer cabinet 205.

In some embodiments, the bracket 200 (or at least one of the plurality of brackets 200) includes a plurality of small clips and large clips into an exterior surface of the bracket 200. In some implementations, portions of the plurality of cables 208 are routed through an interior space of the bracket 200 or the plurality of brackets 200 located between the spine bar and the computing devices in the computer cabinet 205. In some implementations, the portion of the cables routed through the interior space are the cable harness trunks that enclose the cables 208. In some implementations, each of the plurality of cables 208 within the interior space includes a furcation point clipped into at least one of the other brackets 200. In some embodiments, the pair of first projections in each of the plurality of brackets 200 is configured to restrict rotation of the bracket 200. In some embodiments, a closed end of each of the plurality of brackets 200 includes a curved surface concave to an interior of the bracket 200, identical to that of the bracket 100. In some implementations, the curved surface is configured for routing the plurality of cables 208 along the length of the spine bar 290 within the concave portion of the curved surface of the bracket 200 or each of the plurality of brackets 200. The curvature of the closed end of the brackets 200 also provides for desirable mechanical flexibility and resiliency suitable for facilitating the fixation of the brackets 200 to the spin bar of a computer cabinet. In some embodiments, the closed end of the bracket 200 may include a surface with multiple curved portions with varying curvatures, as shown in FIGS. 1B and 1E. As described above, in some implementations, the plurality of brackets 200 are used to route the plurality of cables 208 within the interior space provided by the curved surfaces of the brackets 200. In some implementations, the concaved surface of the closed end of the brackets 200 provide additional space for routing more cables compared to brackets having a closed end with a flat surface.

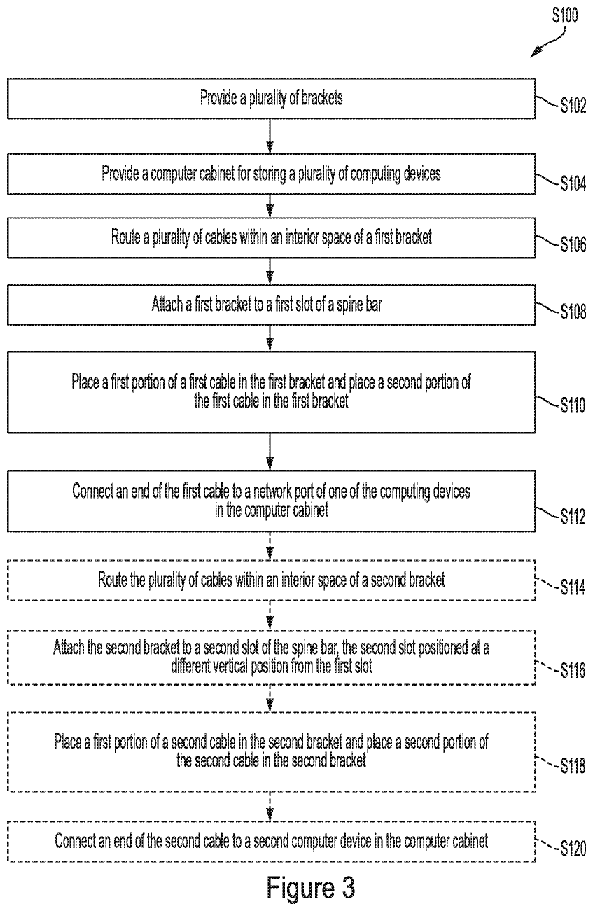

FIG. 3 is a flowchart for an example method S100 of assembling a system for managing cables, according to an illustrative implementation. The method S100 includes providing a plurality of brackets as described herein at step S102. In some implementations, the bracket is the same as the bracket 100 and bracket 200 as illustrated and described with respect to FIGS. 1A, 1B, 1C, 1D, 2A and 2B, and therefore the details of the bracket will not be further described herein.

The method S100 includes providing a computer cabinet for storing a plurality of computing devices at step S104. In some implementations, the computing devices each includes one or more network ports. In some implementations, the computer cabinet includes a spine bar having a plurality of slots along the length of the spine bar at different vertical heights from a bottom of the cabinet.

The method S100 includes routing a plurality of cables within an interior space of a first bracket at step S106. The method S100 includes attaching the first bracket to a first slot of the spine bar at step S108. The method S100 includes placing a first portion of a first cable in the first bracket and placing a second portion of the first cable in the first bracket at step S110. In some implementations, step S110 includes placing a first portion (e.g., a neck) of a first cable furcation point in a small clip of the first bracket and placing a second portion of the first cable furcation point (e.g., a body) in a large clip of the first bracket. In some embodiments, the small clip is vertically aligned to the large clip. The method S100 includes connecting an end of the first cable to a network port of one of the computing devices in the computer cabinet at step S112. In some implementations, the computer device to which the end of the first cable is connected is at about the same vertical height within the computer cabinet as the first bracket.

In some implementations, the method S100 optionally includes routing the plurality of cables within an interior space of a second bracket at step S114.

In some implementations, the method S100 optionally includes attaching the second bracket to a second slot of the spine bar, the second slot positioned at a different vertical position from the first slot at step S116.

In some implementations, the method S100 optionally includes placing a furcation point of a second cable in the second bracket and placing a second portion of the second cable in the second bracket, at step S118. In some implementations, step S118 includes placing a first portion of a second cable furcation point in a small clip of the second bracket and placing a second portion of the second cable furcation point in large clip of the second bracket. In some implementations, the small clips is vertically aligned to the large clip.

In some implementations, the method S100 optionally includes connecting an end of the second cable to a second computer device in the computer cabinet at step S120.

While this specification contains many specific implementation details, these should not be construed as limitations on the scope of any inventions or of what may be claimed, but rather as descriptions of features specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

References to “or” may be construed as inclusive so that any terms described using “or” may indicate any of a single, more than one, and all of the described terms. The labels “first,” “second,” “third,” and so forth are not necessarily meant to indicate an ordering and are generally used merely to distinguish between like or similar items or elements.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

1. A bracket for managing cables, comprising:
a u-shaped body having an open end, closed end, and two side legs;
a pair of first projections extending from surfaces of the side legs towards an interior of the bracket located between the two side legs, with each of the first projections extending from a different side leg;
a pair of second projections extending from the two side legs towards the interior of the bracket, each of the second projections spaced away from the closed end of the bracket and extending from a different side leg, and the pair of first projections is located closer to the open end of the bracket than the pair of second projections;
a plurality of small clips disposed on an outer surface of each of the two side legs, each of the plurality of small clips configured for holding a first portion of a cable furcation point; and
a plurality of large clips disposed on the outer surface of the two side legs, each of the large clips configured for holding a second portion of the cable furcation point.

2. The bracket of claim 1, wherein the plurality of small clips are disposed at a first vertical position of the u-shaped body, a first portion of the plurality of large clips is disposed at a second vertical position of the u-shaped body, and another portion of the plurality of large clips is disposed at a third vertical position of the u-shaped body, wherein vertical refers to a direction normal to the lengths the side legs.

3. The bracket of claim 1, wherein the plurality of large clips alternate along the lengths of the side legs between being positioned at the second vertical position and the third vertical position.

4. The bracket of claim 1, wherein each of the plurality of small clips is vertically aligned to a respective large clip.

5. The bracket of claim 1, wherein the closed end of the u-shaped body comprises a curved surface concave to an interior of the bracket.

6. The bracket of claim 1, wherein the closed end of the u-shaped body is configured for routing cables along a length of a spine bar of a computer cabinet.

7. The bracket of claim 6, wherein the bracket can affix to the spine bar using a single first projection.

8. The bracket of claim 1, wherein the first side leg is spaced from the second side leg by about the width of a main frame computer spine bar.

9. The bracket of claim 1, wherein the first projections are longer vertically than the second projections.

10. The bracket of claim 1, further comprising:
a pair of third projections, each of the third projections positioned on a surface of one of the two side legs, vertically aligned with one of the second projections.

11. The bracket of claim 1, each of the plurality of small clips comprises a pair of straight opposing prongs that are sufficiently flexible or rigid, shaped and sized to securely hold the first portion of the cable furcation point.

12. The bracket of claim 1, each of the plurality of large clips comprises a pair of curved opposing prongs that are sufficiently flexible or rigid, shaped and sized to securely hold the second portion of the cable furcation point.

13. A system for managing cables, comprising:
a plurality of brackets of claim 1; and
a computer cabinet for storing a plurality of computing devices having network ports therein, the computer cabinet comprising a spine bar,
wherein the plurality of brackets are reversibly attached to the spine bar and wherein each of the plurality of brackets is configured to fasten a plurality of cables along a length of the spine bar.

14. The system of claim 13, wherein the spine bar comprises a plurality of slots wherein each of the plurality of slots is configured for snapping in a pair of first projections from a bracket of the plurality of brackets.

15. The system of claim 14, wherein the plurality of brackets are attached to the spine bar along the length of the spine bar at different vertical heights from a bottom of the cabinet.

16. The system of claim 13, wherein at least one of the plurality of brackets includes a plurality of cable furcation points clipped into an exterior surface of the bracket and a plurality of cables routed through an interior space of the bracket located between the spine bar and the computing devices in the cabinet, where each of the cables in the interior space includes a furcation point clipped into at least one of the other brackets.

17. The system of claim 13, wherein the pair of first projections in each of the plurality of brackets is configured to restrict rotation of the bracket.

18. The system of claim 13, wherein the closed end of each of the plurality of brackets comprises a curved surface concave to an interior of the bracket, the curved surface configured for routing cables along the length of the spine bar at least partially within the concave portion of the curved surface.

19. A method of assembling a system for managing cables, the method comprising:
providing a plurality of brackets of claim 1;
providing a computer cabinet for storing a plurality of computing devices having network ports therein, the computer cabinet comprising a spine bar having a plurality of slots along the length of the spine bar at different vertical heights from a bottom of the cabinet;
routing a plurality of cables within an interior space of a first bracket;
attaching the first bracket to a first slot of the spine bar;
placing a first portion of a first cable furcation point in a small clip of the first bracket and placing a second portion of the first cable furcation point in a large clip of the first bracket, the small clip is vertically aligned to the large clip; and
connecting an end of the first cable to a first computing device in the computer cabinet.

20. The method of claim 19, further comprising:
routing the plurality of cables within an interior space of a second bracket;
attaching the second bracket to a second slot of the spine bar, the second slot positioned at a different vertical position from the first slot;
placing a first portion of a second cable furcation point in a small clip of the second bracket and placing a second portion of the second cable furcation point in a large clip of the second bracket, the small clip is vertically aligned to the large clip; and
connecting an end of the second cable to a second computing device in the computer cabinet.

21. A method of assembling a system for managing cables, the method comprising:
providing a plurality of brackets;
providing a computer cabinet for storing a plurality of computing devices having network ports therein, the computer cabinet comprising a spine bar having a plurality of attachment locations along the length of the spine bar at different vertical heights from a bottom of the cabinet;
routing a plurality of cables within an interior space of a first bracket;
attaching the first bracket to a first attachment location of the spine bar;
placing a furcation point of a first cable in the first bracket;
connecting an end of the first cable to a first computing device in the computer cabinet;
routing the plurality of cables within an interior space of a second bracket;
attaching the second bracket to a second attachment location of the spine bar, the second attachment location positioned at a different vertical position from the first slot;
placing a furcation point of a second cable in the second bracket; and
connecting an end of the second cable to a second computing device in the computer cabinet.
